(19) United States
(12) Patent Application Publication
(10) Pub. No.: US 2015/0143186 A1
(43) Pub. Date: May 21, 2015

(54) SYSTEMS AND METHODS FOR DETECTING A DIMM SEATING ERROR

(71) Applicant: Melvin K. Benedict, Magnolia, TX (US)

(72) Inventor: Melvin K. Benedict, Magnolia, TX (US)

(73) Assignee: HEWLETT-PACKARD DEVELOPEMENT COMPANY, Houston, TX (US)

(21) Appl. No.: 14/395,951

(22) PCT Filed: Jul. 27, 2012
(86) PCT No.: PCT/US2012/048626

§ 371 Date: Oct. 21, 2014

(51) Int. Cl. G11C 29/08

(52) U.S. Cl. CPC G11C 29/08
USPC 714/718

(57) ABSTRACT

DIMM seating errors may be detected. An example detection method includes determining whether a training error has occurred for a number of dynamic random access memories (DRAMs) of a DIMM. The Example method includes identifying a location for each of the DRAMs. The example method includes determining whether a seating error has occurred based on the training error, the number, and the location of the DRAMs.

### BACKGROUND

In many computing devices, such as personal computers (PCs), random access memory (RAM) takes the form of dual inline memory modules (DIMMs). DIMMs interface with a bus or interconnect via slots configured to seat individual DIMMs. A DIMM is properly seated when making good contact in the DIMM slot. A DIMM that does not make good contact degrades the performance of the PC. Whereas DIMMs are typically installed to improve the speed of computer processing, a poorly seated DIMM has the opposite effect. Further, PCs with poorly seated DIMMs do not take advantage of all the memory in the DIMM, and cause the PC to report numerous errors. Additionally, a poorly-seated DIMM that makes intermittent contact could generate serious errors, uncorrectable errors.

### BRIEF DESCRIPTION OF THE DRAWINGS

Certain examples are described in the following detailed description and in reference to the drawings, in which:

FIG. 1 is a block diagram of an example system that be used to detect a dual in-line memory module (DIMM) seating error;

FIG. 2 is a perspective view of a memory bank with several DIMMs, in accordance with examples;

FIG. 3 is a process flow chart of an example method to detect a DIMM seating error; and

FIG. 4 is a block diagram showing an example tangible, non-transitory, machine-readable medium that stores code adapted to detect DIMM seating errors.

### DETAILED DESCRIPTION

Because of the impact on the proper processing of computing devices, companies that manufacture personal computers (PCs) and other such devices try to detect and re-seat poorly-seated dual in-line memory modules (DIMMs) before shipping to customers and retailers. However, detection methods are prone to errors, resulting in an unnecessary and costly step, e.g., algorithmically re-seating a properly seated DIMM. Further, manufacturing groups estimate a rate of 2,000-5,000 detects per million with first-time insertion failures. These metrics include installed computing platforms, e.g., servers and PCs. This represents a significant manufacturing cost to identify the failing DIMMs and reseat or replace them. Typically, staged connectors and additional hardware on the DIMM and platform are used to detect poorly seated components. However, an example system detects DIMM seating errors using the basic input output system (BIOS) of the computing device.

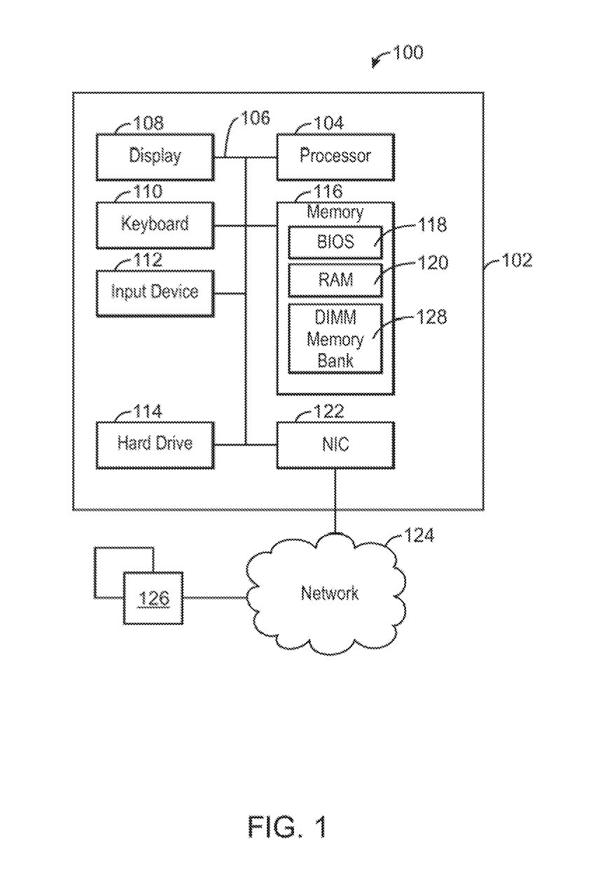

FIG. 1 is a block diagram of an example system 100 that may be used to detect a DIMM seating error. The functional blocks and devices shown in FIG. 1 may include hardware elements including circuitry, software elements including computer code stored on a tangible, non-transitory, machine-readable medium, or a combination of both hardware and software elements. Additionally, the functional blocks and devices of the system 100 are but one example of functional blocks and devices that may be implemented in examples. The system 100 can include any number of computing devices, such as cell phones, personal digital assistants (PDAs), computers, servers, laptop computers, or other computing devices.

The example system 100 can include a computer 102 having a processor 104 connected through a bus 106 to a display 108, a keyboard 110, and an input device 112, such as a mouse, touch screen, and so on. The computer 102 may also include tangible, computer-readable media for the storage of operating software and data, such as a hard drive 114 or memory 116. The hard drive 114 may include an array of hard drives, an optical drive, an array of optical drives, a flash drive, and the like. The memory 116 may be used for the storage of programs, data and operating software, and may include, for example, the BIOS 118, random access memory (RAM) 120, and a DIMM memory bank 128.

The BIOS 118 typically controls the start-up process of a computer system. In so doing, the BIOS 118 may perform a number of functions, including identifying, testing, and initializing system devices, such as memory 116, man-machine interfaces, network interfaces, disk drives, and the like. After initialization, the BIOS 118 may start an operating system and may pass part or all of the functions to the operating system.

The BIOS 118 performs a training process on DIMMs in the DIMM memory bank 128. The training process is the process that the controller uses to establish reliable signal path between the controller and the DRAM storage elements in the DIMMs. A training error represents an issue with the memory bank 128. In the example system, a poorly seated DIMM causes a training error. Thus, in the event of a training error, the BIOS 118 determines whether the DIMM generating the training error is poorly seated. If the DIMM is poorly seated, an error message may be generated specifying the poorly-seated DIMM.

The BIOS 118 is typically stored on a read-only memory (ROM) chip. However, example systems are not limited to the BIOS 118 stored on a ROM chip, as other configurations can be used in the present techniques. For example, a code sequence in a ROM can be used to load a BIOS image to the RAM 120 from the hard drive 114. The computer can then be booted from the BIOS image in the RAM 120. In an example, the BIOS image update may be applied to the stored BIOS image on the hard drive. Any number of other configurations that can be used will be recognized by those of ordinary skill In the art in light of the disclosure contained herein.

The computer 102 can be connected through the bus 106 to a network interface card (NIC) 122. The NIC 122 can connect the computer 102 to a network 124. The network 124 may be a local area network (LAN), a wide area network (WAN), or another network configuration. The network 124 may include routers, switches, modems, or any other kind of interface devices used for interconnection. Further, the network 124 may include the Internet or a corporate networks The computer 102 may communicate over the network 124 with one or more remote computers 123. The remote computers 126 may be configured similarly to the computer 102.

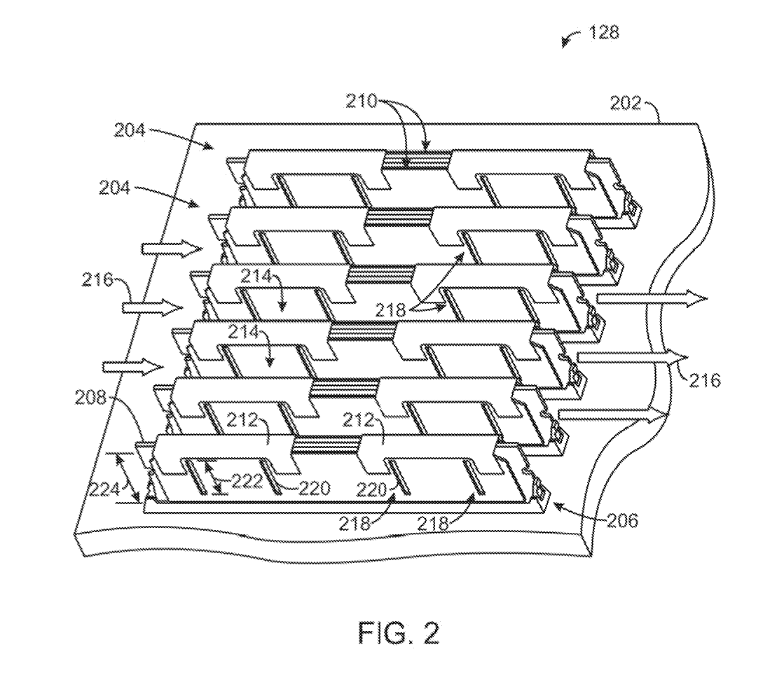

FIG. 2 is a perspective view of the memory bank 128 with several DIMMs, in accordance with examples. The memory bank 128 may be disposed on a circuit board 202 and may include one or more DIMM packages 44 installed in memory slots 206. The memory bank 128 may be included in any suitable computer system, for example, a desktop computer, a blade server, and the like.

Each DIMM package 204 may include a DIMM 208, heat spreaders 210, and clips 212. The DIMM 208 may include one or more memory chips, which may include any suitable type of memory, for example, static random access memory (SRAM), dynamic random access memory (DRAM), synchronous DRAM (SDRAM), double-data-rate (DDR) SDRAM, and the like.

The heat spreaders 210 may include any suitable thermally conductive material. to disburse heat from the DIMM 208. The clips 212 may straddle the top edge of the DIMM package 204 and grip the sides of the heat spreaders 210 to hold the heat spreaders 210 in contact with the DIMM 208. The clips 212 may be made of any suitable resilient material, for example, aluminum, plastic, and the like.

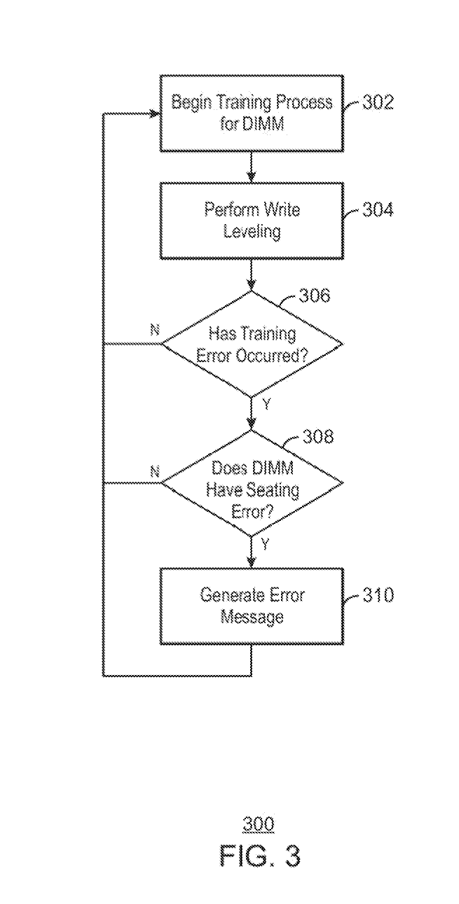

FIG. 3 is a process flow chart of an example method 300 to detect a DIMM seating error. The method 300 is performed by the BIOS 118, and begins at block 302, where the BIOS 118 begins the training process for each DIMM 208. At block 304, the BIOS 118 performs the WRITE LEVELING process. WRITE LEVELING is part of the training process for DDR3 and DDR4 DIMMs.

At block 306, the BIOS 118 determines whether a training error has occurred. The WRITE LEVELING process varies the relationship between the clock and data line (DQ) sequence (DQS). The DQS represents a timing signal between the controller and the DRAM storage elements indicating valid data during ran training mode operation. Each individual DRAM senses the relationship between those 2 signals and returns the results on DQS for DDR3 and all DQs for DDR4. This results in a DQ sequence of 101 or 010 being returned. If either of these sequences is not observed, a training error has occurred.

If a training error occurs, at block 308, the BIOS 118 determines whether the DIMM generating the training error has a seating error. By analyzing the pattern of training errors as they occur, a determination of a seating error can be determined. For example, uniformly failing DRAM across the entire DIMM does not indicate a poorly seated DIMM because the uniformly failing DRAM indicates the I2C interface. is not working. If the I2C interface is not working, the DIMM being inserted in that location is not detected (assuming the inserted DIMM inventory is saved between boot cycles).

However, if a single DRAM fails and it is located near the end of the DIMM, the DIMM may be poorly seated. Also, single bit failures (DDR4) indicate a possible contamination issue, which may be resolved by cleaning the DIMM and re-seating. Further, if there are training errors for multiple DRAMs, a poorly seated DIMM is indicated by the DRAMs being grouped near one end of the DIMM. Additionally, a DIMM that returns valid WRITE LEVELING data while not being detected also indicates a poorly seated DIMM. If there is a seating error, at block 310, a message indicating the DIMM with the seating error is generated.

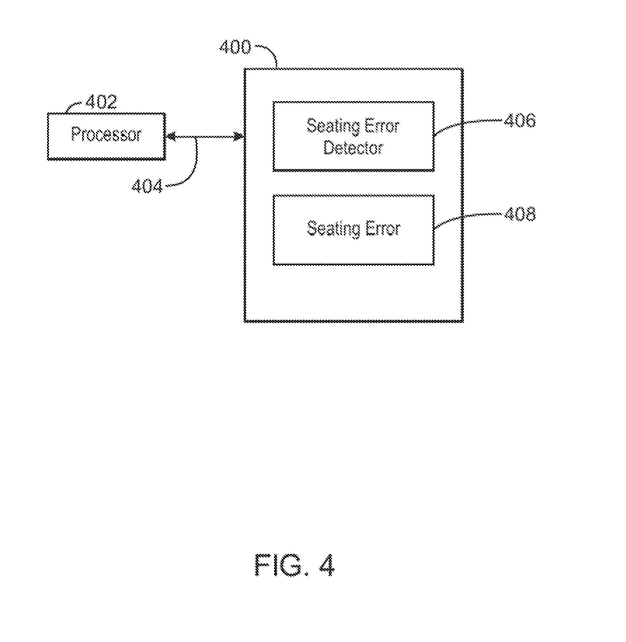

FIG. 4 is a block diagram showing an example tangible, non-transitory, machine-readable medium 400 that stores code adapted to detect DIMM seating errors. The machine-readable medium is generally referred to by the reference number 400. The machine-readable medium 400 may correspond to any typical storage device that stores computer-implemented instructions, such as programming code or the like. Moreover, the machine-readable medium 400 may be included in the storage 122 shown in FIG. 1. When read and executed by a processor 402, the instructions stored on the machine-readable medium 400 are adapted to cause the processor 402 to detect DIMM seating errors. The medium includes a seating error detector 406. The seating error detector 406 receives a training sequence for each DRAM of a DIMM module. If the training sequences indicate one or more training errors, the seating error detector 406 determines whether there is a seating error 408 for the DIMM based on the location of the DRAM, and the number of DRAMs with training errors. The seating error detector generates a message indicating the seating error, and specifying the DIMM module.

What is claimed is:

1. A method for detecting a dual in-line memo module (DIMM) seating error, the method comprising:
determining whether a training error has occurred for a number of dynamic random access memories (DRAMs) of a DIMM;
identifying a location for each of the DRAMs; and
determining whether a seating error has occurred based or the training error, the number, and the location of the DRAMs.

2. The method recited in claim 1, wherein the seating error has occurred if the number equals one.

3. The method recited in claim 1, wherein the seating error has occurred if the number is greater than one, and the location is disposed approximate to an end of the DIMM.

4. The method recited in claim 1, wherein the seating error has not occurred if the number indicates a universal failure of the DRAMs.

5. The method recited in claim 1, wherein a WRITE LEVELING process comprises determining whether the seating error has occurred

6. The method recited in claim 1, wherein the DIMM comprises DDR3 and DDR4 DRAMS.

7. The method recited in claim 1, comprising generating an error message indicating the seating error and the DIMM.

8. The method recited in claim 1, comprising:
removing the DIMM; and
re-seating the DIMM.

9. The method recited in claim 8, comprising removing a contaminant from the DIMM.

10. The method recited to claim 1, where the seating error has occurred if:
the DIMM that returns valid WRITE LEVELING data; and
the DIMM is not detected.

11. A computer system for detecting DIMM seating errors, the computer system comprising;
a processor that is adapted to, execute stored instructions; and
a memory device that stores instructions, the memory device comprising:
computer-implemented code adapted to determine whether a training error has occurred for a number of dynamic random access memories (DRAMs) of a DIMM;
computer-implemented code adapted to identity a location for each of the DRAMs; and
computer-implemented code adapted to determine whether a seating error has occurred based on the training error, the number, and the location of the DRAMs, wherein a WRITE LEVELING process comprises determining whether the seating error has occurred.

12. The computer system recited in claim 11, wherein the seating error has occurred if the number equals one.

13. The computer system recited in claim 11, wherein the seating error has occurred if the number is greater than one, and the location is disposed approximate to an end of the DIMM.

14. The computer system recited in claim 11, therein the seating error has not occurred if the number indicates a universal failure of the DRAMs.

15. The computer system recited in claim 11, where the seating error has occurred if:
the DIMM that returns valid WRITE LEVELING data; and
the DIMM is not detected.

16. The computer system recited in claim 11, wherein the DIMM comprises DDR3 and DDR4 DRAMS.

17. The computer system recited in claim 11, comprising computer-implemented code adapted to generate an error message indicating the seating error and the DIMM.

18. The computer system recited in claim 11, comprising:
means for removing the DIMM; and
means for re-seating the DIMM.

19. The computer system recited in claim 18, comprising means for removing a contaminant from the DIMM.

20. A tangible, non-transitory machine-readable medium that stores machine-readable instructions executable by a processor to detect DIMM seating errors, the tangible, non-transitory, machine-readable medium comprising:
machine-readable instructions that, when executed by the processor, determine whether a training error has occurred for a number of dynamic random access memories (DRAMs) of a DIMM;
machine-readable instructions that, when executed by the processor, identify a location for each of the DRAMs;
machine-readable instructions that, when executed by the processor, determine whether a seating error has occurred based on the training error, the number, and the location of the DRAMs; and
machine-readable instructions that, when executed by the processor, generate an error message indicating the seating error and the DIMM.
